(19) United States
(12) Patent Application Publication
(10) Pub. No.: US 2010/0164933 A1
(43) Pub. Date: Jul. 1, 2010

(54) LCD SOURCE DRIVER

(76) Inventors: Sang-Hoon Lim, Jungnang-gu (KR); Tae-Woon Kim, Anyang-si (KR); Shin-Young Yi, Seongnam-si (KR); Jin-Seok Koh, Yongin-si (KR)

Correspondence Address: SHERR & VAUGHN, PLLC, 620 HERNDON PARKWAY, SUITE 320, HERNDON, VA, 20170, US

(21) Appl. No.: 12/634,815

(22) Filed: Dec. 10, 2009

(30) Foreign Application Priority Data
Dec. 26, 2008 (KR) 10-2008-0134209

(51) Int. Cl. G09G 5/00; H03M 1/66

(52) U.S. Cl. 345/211; 341/144

(57) ABSTRACT

An LCD source driver may include a digital-to-analog converter including a sampling capacitor to sample, according to a signal, at least one of a first voltage and a second voltage. The LCD source driver may also include a reconstruction filter in which capacitance applied from the sampling capacitor according to the signal and capacitance of an integral capacitor for holding a previous output voltage are connected in parallel.

The present application claims priority under 35 U.S.C. 119 to Korean Patent Application No. 10-2008-0134209 (filed on 26 Dec. 2008), which is hereby incorporated by reference in its entirety.

### BACKGROUND

A source driver for driving a Liquid Crystal Display (LCD) may use a register string (R-string) digital-to-analog converter (DAC) structure. However, recently, to achieve higher quality, a source driver IC of 10 bits or more has been developed. An R-string DAC, which may be used when implementing the existing source driver, implements up to 8 bits. However, when a high resolution of 10 bits or more is implemented, 2N (N is number of bits) routings and resistors are necessary and thus the area of a chip is rapidly increased.

For this reason, a source driver using a sigma-delta DAC type structure was suggested. The schematic structure of the sigma-delta DAC for the source driver is shown in FIG. 1. Referring to FIG. 1, a K-bit DAC and an analog reconstruction filter are necessary. However, since power consumption and chip area are required to be minimized for a source driver chip, appropriate optimization is necessary.

### SUMMARY

Embodiments relate to a semiconductor device, and more particularly, to a Liquid Crystal Display (LCD) source driver. Embodiments relate to a Liquid crystal Display (LCD) source driver with a small area, low power consumption and a fast settling time.

Embodiments relate to a Liquid Crystal Display (LCD) source driver which may include a digital-to-analog converter including a sampling capacitor to sample, according to a signal, at least one of a first voltage and a second voltage. The LCD source driver may also include a reconstruction filter in which capacitance applied from the sampling capacitor according to the signal and capacitance of an integral capacitor for holding a previous output voltage are connected in parallel.

Embodiments relate to a Liquid Crystal Display (LCD) source driver which may include a digital-to-analog converter including a sampling capacitor to sample a first voltage or a second voltage according to a signal, and a reconstruction filter configured to select a reference signal using some M bits of N bits, when N bits are implemented, and to perform digital-to-analog conversion using a delta-sigma conversion method using the remaining N-M bits.

With the LCD source driver of embodiments, it is possible to implement a small area and low power consumption by forming a digital-to-analog converter and a reconstruction filter using one block and to improve a settling time of an output by adjusting a reference voltage.

### DRAWINGS

FIG. 1 is a block diagram showing the configuration of a related Liquid Crystal Display (LCD) source driver.

FIG. 2 is a circuit diagram of an LCD source driver according to embodiments.

FIGS. 3A and 3B are detailed circuit diagrams of the LCD source driver according to embodiments.

FIG. 4 is a circuit diagram showing an LCD source driver according to embodiments.

FIGS. 5A and 5B are detailed circuit diagrams of the LCD source driver according to embodiments.

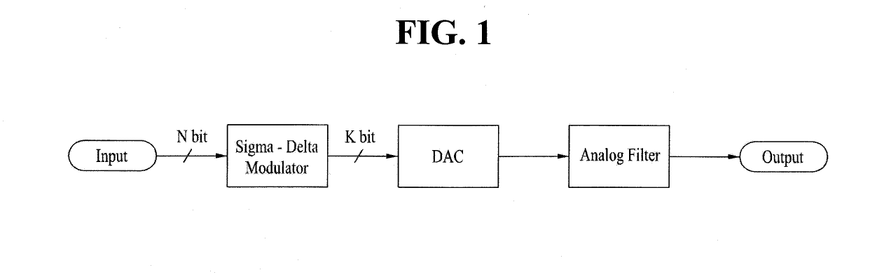

### DESCRIPTION

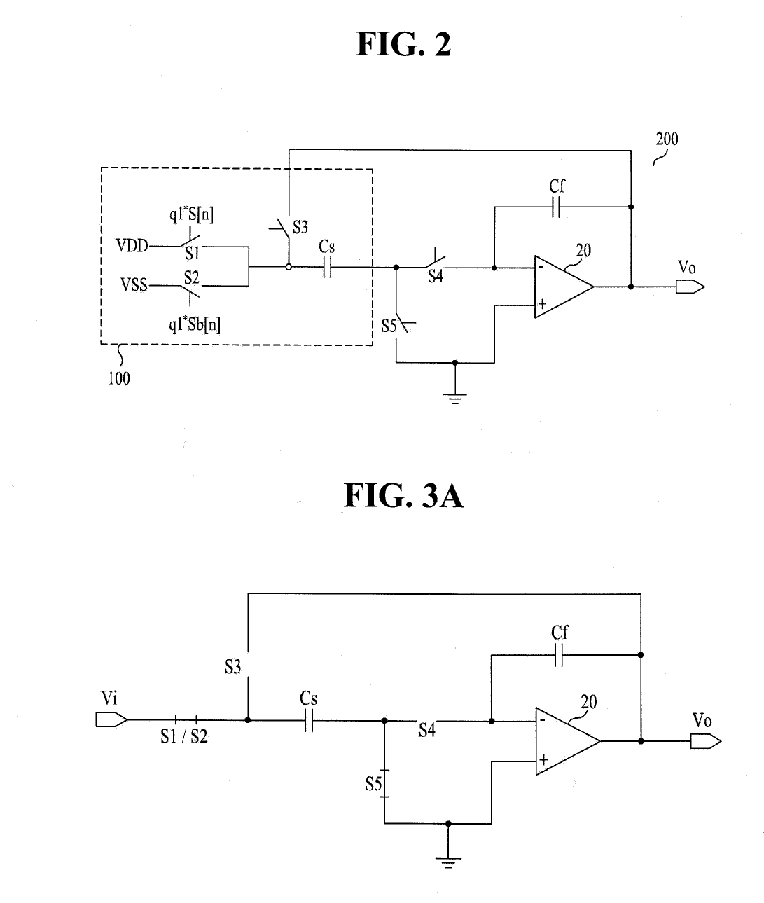

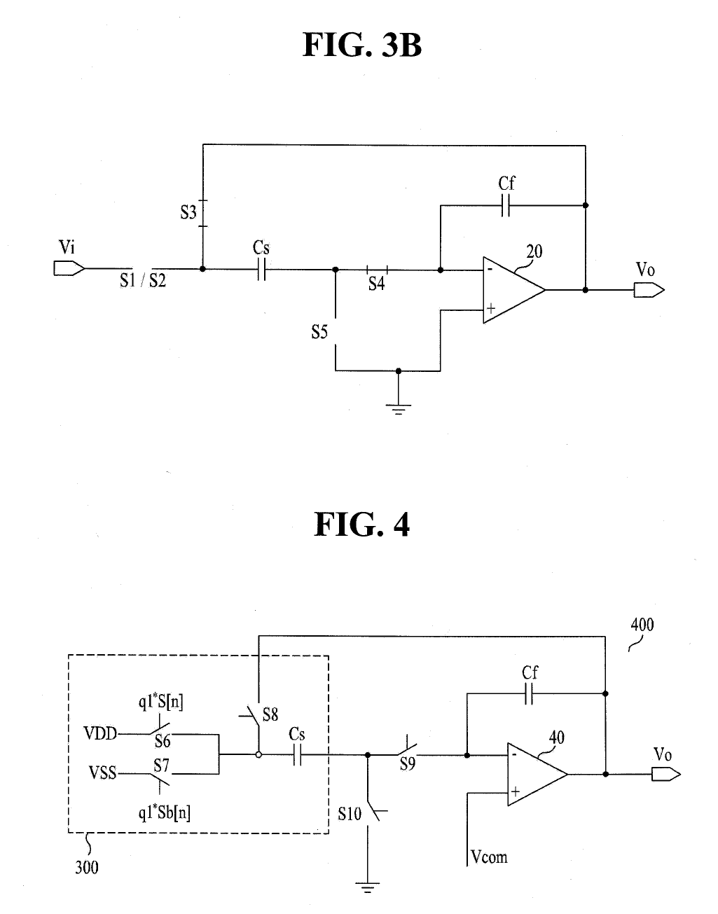

Hereinafter, a Liquid Crystal Display (LCD) source driver according to embodiments will be described with reference to example FIG. 2 and example FIGS. 3A and 3B. Example FIG. 2 is a circuit diagram of an LCD source driver according to embodiments. As shown in example FIG. 2, in embodiments, in the use of a signal-delta digital-to-analog converter (DAC) when a source driver of 10 bits or more is designed, a core-DAC and an analog filter may be implemented using one block. In addition, a settling time of a final output can be improved by adjusting a reference voltage.

The source driver shown in example FIG. 2 includes a 1-bit DAC 100. As shown in example FIG. 2, the source driver of embodiments may include the DAC 100 including a first switch S1 connected to a source voltage VDD, a second switch S2 connected to a ground voltage VSS, and a sampling capacitor Cs for sampling an input signal. The source driver may also include a reconstruction filter 200 including a third switch S3 connected between the sampling capacitor Cs and an operational amplifier 20, a fourth switch S4 connected between the sampling capacitor Cs and the operational amplifier 20, a fifth switch S5 connected between the sampling capacitor Cs and the operational amplifier 20, and an integral capacitor Cf connected between an output node 30 and the DAC 100.

The integral capacitor Cf may be connected between an output terminal and an input terminal of the operational amplifier 20 so as to configure a feedback loop. S[n] denotes the output of a sigma-delta modulator. Sb[n] denotes the inverted output of the sigma-delta modulator. The DAC 100 samples the source voltage VDD when S[n] is “High” and samples the ground voltage VSS when S[n] is “Low”.

When the DAC 100 denoted by a dotted line is extended in parallel, a multi-bit DAC may be implemented. Operation modes according to clocks q1 and q2 are shown in example FIGS. 3A and 3B. As shown in example FIG. 3A, when the clock q1 is at a logic “High” level, the first switch S1 and the fifth switch S5 may be turned on and the second switch S2, the third switch S3 and the fourth switch S4 may be turned off. The input voltage VDD or VSS may be sampled by the sampling capacitor Cs. At this time, the feedback capacitor Cf holds a previous output voltage.

As shown in example FIG. 3B, when the clock q2 is at a logic “High” level, the second, third and fourth switches S2, S3 and S4 may be turned on and the first and fifth switches S1 and S5 may be turned off. Accordingly, the sampling capacitor Cs and the integral capacitor Cf may be connected in parallel such that electric charges in the sampling capacitor Cs may be transferred to the integral capacitor Cf

$$H ( Z ) = \frac{Cs}{Cs + Cf} * \frac{1}{1 - \frac{Cf}{Cs + Cf} * {z}^{- 1}} \qquad Equation 1$$

As a result, the transfer function of the circuit is obtained by Equation 1, which has primary low-pass filter characteristics. In embodiments, it may be possible to implement a small area and low power consumption by implementing the core-DAC and the analog reconstruction filter using one block.

Hereinafter, an LCD source driver according to embodiments will be described with reference to example FIG. 4. As shown in example FIG. 4, the LCD source driver of embodiments may include a DAC 300 and a reconstruction filter 400. The source driver of embodiments may include the DAC 300 including a sixth switch S6 connected to a source voltage VDD, a seventh switch S7 connected to a ground voltage VSS and a sampling capacitor Cs for sampling an input signal. The reconstruction filter 400 may also include an eighth switch S8 connected between the sampling capacitor Cs and an operational amplifier 40, a ninth switch S9 connected between the sampling capacitor Cs and the operational amplifier 40, a tenth switch S10 connected between the sampling capacitor Cs and the operational amplifier 40, and an integral capacitor Cf connected between an output node 60 and the DAC 300.

The integral capacitor Cf may be connected between an output terminal and an input terminal of the operational amplifier 40 so as to configure a feedback loop. When N bits are implemented, the DAC 300 selects a reference voltage Vcom using some M bits of N-bit data and performs DAC using a delta-sigma conversion method based on the remaining N-M bits of the N-bit data. Here, M may be a real number less than N-M. That is, the circuit of embodiments may adjust the reference voltage Vcom of the operational amplifier 40 according to the input bits of the DAC 300, for faster settling time.

An output voltage Vo becomes a voltage level corresponding to the remaining N-M bits on the basis of the selected reference voltage Vcom. Accordingly, the output voltage Vo is precharged to the reference voltage Vcom, and, as a result, an output settling time becomes fast. When the DAC 100 denoted by a dotted line is extended in parallel, a multi-bit DAC may be implemented.

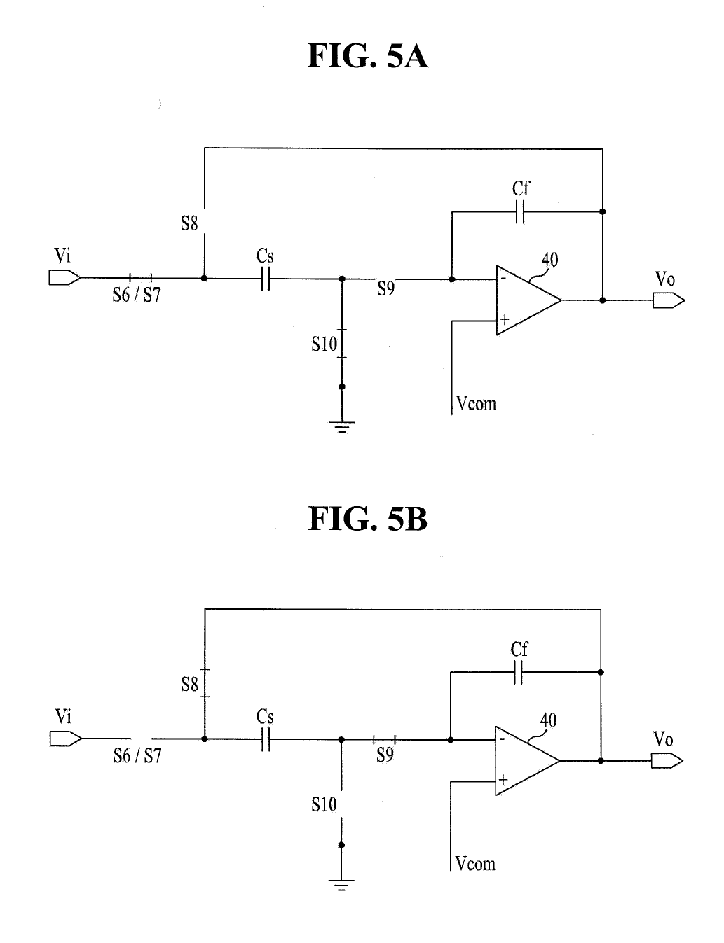

Operation modes according to clocks q1 and q2 are shown in example FIGS. 5A and 5B. As shown in example FIG. 5A, when the clock q1 is at a logic “High” level, the sixth switch S6 and the tenth switch S10 may be turned on and the seventh switch S7, the eighth switch S8 and the ninth switch S9 may be turned off. The input voltage VDD or VSS may be sampled by the sampling capacitor Cs. At this time, the feedback capacitor Cf holds a previous output voltage.

As shown in example FIG. 5B, when the clock q2 is at a logic “High” level, the seventh, eighth and ninth switches S7, S8 and S9 may be turned on and the sixth and tenth switches S6 and S10 are turned off. Accordingly, the sampling capacitor Cs and the integral capacitor Cf may be connected in parallel such that electric charges charged in the sampling capacitor Cs are transferred to the integral capacitor Cf.

$$H ( Z ) = \frac{Cs}{Cs + Cf} * \frac{1}{1 - \frac{Cf}{Cs + Cf} * {z}^{- 1}} \qquad Equation 2$$

As a result, the transfer function of the circuit may be obtained by Equation 2, which has primary low-pass filter characteristics. In embodiments, it is possible to implement a small area and low power consumption by implementing the DAC and the analog reconstruction filter using one block. In addition, it is possible to improve a settling time by adjusting a reference voltage.

It will be obvious and apparent to those skilled in the art that various modifications and variations can be made in the embodiments disclosed. Thus, it is intended that the disclosed embodiments cover the obvious and apparent modifications and variations, provided that they, are within the scope of the appended claims and their equivalents.

What is claimed is:

1. A liquid crystal display source driver comprising:
a digital-to-analog converter including a sampling capacitor to sample, according to a signal, at least one of a first voltage and a second voltage; and
a reconstruction filter in which capacitance applied from the sampling capacitor according to the signal and capacitance of an integral capacitor for holding a previous output voltage are connected in parallel.

2. The liquid crystal display source driver of claim 1, wherein the first voltage is a source voltage.

3. The liquid crystal display source driver of claim 1, wherein the second voltage is a ground voltage.

4. The liquid crystal display source driver of claim 1, wherein the a digital-to-analog converter is a 1-bit digital-to-analog converter.

5. The liquid crystal display source driver of claim 1, wherein the first voltage and the second voltage are each connected to the sampling capacitor by a switch controlled by the signal.

6. The liquid crystal display source driver of claim 1, wherein the reconstruction filter includes a third switch connected between the sampling capacitor and the output of an operational amplifier.

7. The liquid crystal display source driver of claim 6, wherein the reconstruction filter includes a fourth switch connected between the sampling capacitor Cs and a first input of the operational amplifier.

8. The liquid crystal display source driver of claim 7, wherein the reconstruction filter includes a fifth switch connected between the sampling capacitor Cs and ground.

9. An liquid crystal display source driver comprising:
a digital-to-analog converter including a sampling capacitor to sample, according to a signal, at least one of a first voltage and a second voltage; and
a reconstruction filter configured to select a reference signal using some M bits of N bits, when N bits are implemented, and to perform digital-to-analog conversion using a delta-sigma conversion method using the remaining N-M bits.

10. The liquid crystal display source driver of claim 9, wherein the first voltage is a source voltage.

11. The liquid crystal display source driver of claim 9, wherein the second voltage is a ground voltage.

12. The liquid crystal display source driver of claim 9, wherein the M bits are smaller than the N-M bits.

13. The liquid crystal display source driver of claim 9, wherein the output voltage of the reconstruction filter is precharged to the reference voltage.

14. The liquid crystal display source driver of claim 9, wherein the reference voltage is adjusted according to the M bits.

15. The liquid crystal display source driver of claim 9, wherein the output voltage of the reconstruction filter is output at a voltage level corresponding to the N-M bits on the basis of the reference voltage.

16. The liquid crystal display source driver of claim 9, wherein the a digital-to-analog converter is a 1-bit digital-to-analog converter.

17. The liquid crystal display source driver of claim 9, wherein the first voltage and the second voltage are each connected to the sampling capacitor by a switch controlled by the signal.

18. The liquid crystal display source driver of claim 9, wherein the reconstruction filter includes a third switch connected between the sampling capacitor and the output of an operational amplifier.

19. The liquid crystal display source driver of claim 18, wherein the reconstruction filter includes a fourth switch connected between the sampling capacitor Cs and a first input of the operational amplifier.

20. The liquid crystal display source driver of claim 7, wherein the reconstruction filter includes a fifth switch connected between the sampling capacitor Cs and ground.
